(19) United States
(12) Patent Application Publication
(10) Pub. No.: US 2017/0207414 A1
(43) Pub. Date: Jul. 20, 2017

(54) DIELECTRIC LAYER, DISPLAY SUBSTRATE COMPRISING THE DIELECTRIC LAYER, AND METHOD FOR MANUFACTURING THE DISPLAY SUBSTRATE

(71) Applicants: BOE TECHNOLOGY GROUP CO., LTD., Beijing (CN); ORDOS YUANSHENG OPTOELECTRONICS CO., LTD., Ordos (CN)

(72) Inventors: Haidong WU, Beijing (CN); Guanyin WEN, Beijing (CN); Renrong GAI, Beijing (CN); Qun MA, Beijing (CN)

(21) Appl. No.: 15/392,640

(22) Filed: Dec. 28, 2016

(30) Foreign Application Priority Data
Jan. 15, 2016 (CN) 201610028669.0

(51) Int. Cl. H01L 51/52; H01L 51/56; H01L 27/32

(52) U.S. Cl. CPC H01L 51/5246; H01L 27/3262; H01L 27/3248; H01L 51/524; H01L 51/56

(57) ABSTRACT

A dielectric layer applicable to a display substrate, comprises at least one metal grain layer which is disposed therein. A display substrate comprising the dielectric layer, and a method for manufacturing such a display substrate are further disclosed.

### TECHNICAL FIELD

Embodiments of the disclosure relate to a dielectric layer, a display substrate comprising the dielectric layer and a method for manufacturing the display substrate.

### BACKGROUND

A structure of organic light emitting device (OLED) essentially comprises an anode layer, a cathode layer, and a light emitting layer sandwiched between the anode layer and the cathode layer, wherein the light emitting layer is one or more organic layer. Under effect of voltages applied externally, electrons and holes are injected into the organic layer from the cathode and from the anode respectively, and they are migrated to the light emitting layer and are recombined with each other so as to generate excitons, energy of which are attenuated in a manner of light, that is to say, light is radiated.

OLEDs are classified into top emission type and bottom emission type, according to their light emitting manner. In a bottom emission type OLED, light is emitted from a side of a thin film transistor and a planarization layer, that is, a side of a first electrode of the OLED, wherein the first electrode is an electrode disposed at the light emitting side and is a transparent electrode (for example, made of Indium Tin Oxides (ITO)). As to the top emission type OLED, the first electrode disposed on the planarization layer is an opaque and reflective electrode (for example, made of reflective material, such as Ag, or Al) and the second electrode which is an electrode disposed at the light emitting side is made of transparent material. With respect to the top emission type OLED, the OLED of the bottom emission type is inclined to be effected by the TFT and has a relative small opening ration. In order to achieve required luminance, it is required to increase luminance of the OLED by increasing driving voltage, for example. However, this will produce negative effect on the lifetime of the device and the material. Thus, requirements on characteristics of the bottom emission type OLED such as lifetime of material and light emitting efficiency will be higher.

In process of emitting light of the OLED, energy lost is mainly due to the following aspects. On one hand, injected carriers are coupled in the light emitting layer so as to emit light, however, not all injected energy are converted into photons, energy of a portion of excitons is lost in non-radiative transition such as lattice vibration, deep level impurity transition and the like. This process reflects a light emitting efficiency, or an efficiency that electrical energy is converted into photo energy, and can be depicted by internal quantum effect. On the other hand, total reflections at interfaces between the anode layer of the OLED and the substrate, between the substrate and the air, and etc., waveguide mode at interface between the anode layer and the light emitting layer of the OLED, and surface plasmons loss at the vicinity of the metal electrodes, or the like, cause that only about 20% of light pass through OLED and enter the air and can be observed by us after the light emitted from the light emitting layer passing through the multiple layers. This process reflects light extraction efficiency from the OLED, i.e., light extraction efficiency or light emitting efficiency, and can be described by external quantum effect. At present, an OLED with an internal quantum effect close 100% can be implemented theoretically through improving properties of material, in spite of few kinds of such materials. Forming surface microstructures on ITO electrodes to reduce waveguide mode loss, adhering photonic crystal or microlens array to glass substrate to reduce total reflection, forming wrinkled cathode to reduce surface plasmons loss, and forming optical microcavity can improve light extraction efficiency of the OLED significantly. However, it is required to utilize nanoimprint technology, which is a complex and difficult process, to adhere photonic crystal or form pattern of periodic or semi-periodic microstructures on the cathode. And meanwhile, microcavity effect is prone to deviate color of light and narrow viewing angles.

### SUMMARY

At least one embodiments of the present disclosure provides a dielectric layer applicable to a display substrate, comprising at least one metal grain layer which is disposed in the dielectric layer.

At least one embodiments of the present disclosure provides a display substrate, comprising the dielectric layer mentioned above, and further comprising a substrate and an OLED device, a light emitting surface of the OLED device facing the substrate, wherein the dielectric layer is disposed between the substrate and the OLED device.

One embodiments of the present disclosure provides a display substrate, further comprising a driving transistor, wherein the driving transistor is disposed over the dielectric layer, and a drain electrode of the driving transistor is electrically connected to the OLED device.

At least one embodiments of the present disclosure provides a display substrate, comprising the dielectric layer according to claim 1, and further comprising a substrate, an OLED device and a package cover plate, wherein the OLED device is disposed between the substrate and the package cover plate, a light emitting surface of the OLED device faces the package cover plate, and the dielectric layer is disposed between the OLED device and the package cover plate.

One embodiment of the present disclosure provides a display substrate further comprises a driving transistor is disposed over the dielectric layer, and a drain electrode of the driving transistor is electrically connected to the OLED device.

At least one embodiments of the present disclosure provides a method for manufacturing a display substrate which is the display substrate mentioned above, the method comprising forming a dielectric layer and forming at least one metal grain layer in the dielectric layer.

In embodiments of the present disclosure, as a metal grain layer is disposed at the light-emitting surface of the OLED device of the display substrate, light-emitting efficiency of the OLED device can be improved significantly and light-emitting efficiency of the display substrate can be improved at the same time.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus the skilled in this art can obtain other drawings from these drawings without any inventive work.

FIG. 1 is an illustrative structural view of an OLED display panel according to one embodiment of the present disclosure;

FIG. 2 is an illustrative structural view of an OLED display panel according to another embodiment of the present disclosure; and

FIG. 3 is a schematic diagram of a method for manufacturing display substrate according to one embodiment of the present disclosure.

### REFERENCE SIGNS

1—base
11—sub-dielectric layer
20—metal material layer
12—metal grain layer
2—driving transistor
3—OLED

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

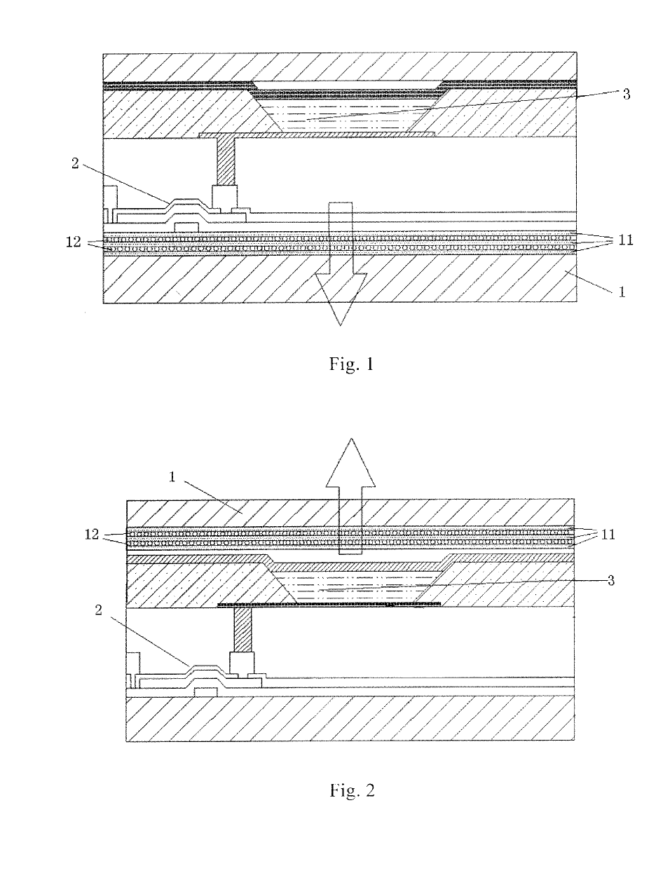

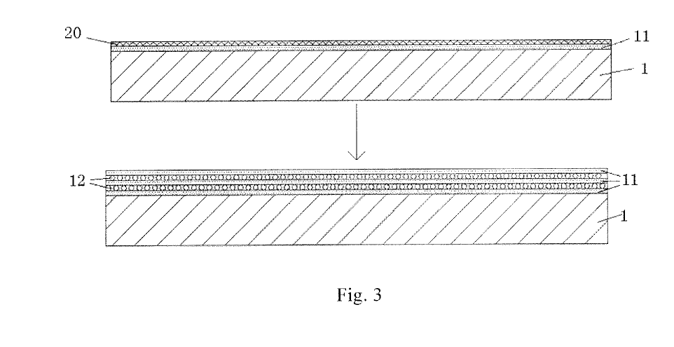

At least one embodiment of the present disclosure provides a dielectric layer applicable to a display substrate, comprising at least one metal grain layer which is disposed in the dielectric layer. As shown in FIG. 1, a dielectric layer comprising at least one metal grain layer 12 disposed therein.

In one embodiment of the present disclosure, the dielectric layer comprises a plurality of the metal grain layer 12 and a plurality of dielectric sub-layer 11, wherein the dielectric sub-layer 11 and the metal grain layers 12 are disposed alternatively. The amount of the metal grain layers and the dielectric sub-layers are not limited in the embodiment, and will be determined according to actual requirements. It should be noted that, in a system with a plurality of metal grain layers 12 and a plurality of dielectric sub-layers 11, it is a dielectric sub-layer 11 that is disposed outmost. The dielectric sub-layers 11 are made of at least one of silicon oxide or silicon nitride, and each of the dielectric sub-layers 11 has a thickness of 2 nm to 10 nm.

At least one embodiment of the present disclosure provides a display substrate, which is an array substrate. As illustrated in FIG. 1, the display substrate comprises: a base substrate 1 and an OLED 3 disposed on the base substrate 1, wherein the OLED 3 is a bottom emission type OLED. The display substrate further comprises a dielectric layer 11 which is disposed between the base substrate 1 and the OLED 3. And further, the display substrate comprises at least one metal grain layer 12, which is disposed in the dielectric layer 11.

As illustrated in FIG. 1, the OLED 3 disposed on the OLED display panel is a bottom emission type OLED. When light emitted from the OLED 3 is irradiated on the metal grain layer 12 disposed on the base substrate 1, light emitting efficiency and light extraction efficiency of the OLED is enhanced through surface plasmons resonance effect of metal grains in the metal grain layer 12. Thus, light outgoing efficiency of the display substrate is enhanced.

Surface plasmons (SPs) are electron dense waves that are generated due to interaction between electrons and photons that exist at the surface of a metal and freely vibrate and that propagate the surface of the metal. The electron dense wave is a electromagnetic surface wave and can confine optical waves broadwise within a range of sub-wavelength. The electron dense wave has a flat dispersion curve and a great optical density of state at a frequency close to its resonant frequency. And the electron dense wave can enhance spontaneous emission of surface plasmons when interacting with an active medium. Field intensity of the surface plasmons is greatest at the surface of a metal film and is attenuated exponentially in a direction perpendicular to an interface of the metal film, and the surface plasmons can be excited by electrons or by optical waves. If a metal film has a very rough surface, or in case of close to curved structure of metal (such as a sphere, a cylinder, and the like), surface plasmons at the surface of the metal cannot propagate along an interface in the manner of wave, and will be confined near surfaces of the structure, which are called localized surface plasmons. When metal grains with a size less than or close to wavelength of a light is irradiated by the light, its oscillating electrical field will make the electron atmosphere of the metal grain move with respect to the core of the metal grain, and the electron atmosphere will oscillate around the core due to resilience generated by coulomb attraction between the electron atmosphere and the core. The collective oscillation of electron atmosphere is called surface plasmon resonance.

In case of surface plasmon resonance, electromagnetic field around the metal grain will be intensified significantly. Then, the metal grain can be considered as a nanolens, and the oscillated surface plasmon is a photon and is confined strongly within a grain with a size of nanometer. It is an important effect generated by the surface plasmons resonance that the scattering cross section and the absorption cross section of the metal grain on the light are increased significantly. An oscillation frequency of the surface plasmons is mainly determined by electron density of the metal grain (i.e., metal specie), effective electron quantity, size and shape of the metal grain, surrounding medium, and other factors. The oscillation frequency of the surface plasmons can be determined by the following equation:

$${w}_{sp} = \frac{{w}_{p}}{\sqrt{1 + 2 {e}_{m}}} ,$$

wherein ωp is the oscillation frequency of the surface plasmons and εₘ is the dielectric constant of the surrounding medium.

The external quantum efficiency (ηₑₓₜ) can be obtained according to the following equation:

$${η}_{ext} = {C}_{ext}^{′} \times {η}_{int} = {C}_{ext}^{′} \times \frac{{κ}_{rad}^{*}}{{κ}_{rad}^{*} + {κ}_{non}^{*}} ;$$

wherein C′ₑₓₜ is the light extraction efficiency, and ηᵢₙₜ is the internal quantum efficiency. And the internal quantum efficiency is determined by a ratio of radiation deactive rate (K_{rad}) to non-radiation deactive rate (Kₙₒₙ). Typically, at room temperature, the radiation deactive rate of an OLED is faster than its non-radiation deactive rate, and a middle internal quantum eficiency ηᵢₙₜ will be generated. The internal quantum efficiency and the light extraction efficiency of OLED will be respectively increased by surface plasmons. The internal quantum efficiency of OLED is increased by surface plasmons on basis of the radiation deactive rate (K_{rad}) and the density of state. When a light-emitting center is located in a micro-cavity with a size in order of wavelength, the density of state of photon will be increased, which causes increase in spontaneous emission of exciton, thereby increasing proportion of the radiation deactive rate. That is to say, the internal quantum efficiency is enhanced. The light extraction efficiency of OLED is enhanced by the surface plasmons as follows: light that is not radiated due to an incident angle greater than the angle of total reflection can excite surface plasmons, and the surface plasmons will be radiated in the manner of light, thereby enhancing the external quantum efficiency. Thus, reasonably utilizing the surface plasmons resonance effect of metal grains can effectively enhance the external quantum efficiency of OLED.

As the OLED 3 on the array substrate according to the embodiment of the disclosure is provided with a metal grain layer 12 at its light emitting side, light extraction efficiency of the OLED 3 on the array substrate can be enhanced significantly, and meanwhile, the light emitting efficiency of a display array utilizing the array substrate can be enhanced.

The array substrate according to the embodiment of the disclosure comprises a plurality of the metal grain layer 12, and the dielectric layer comprises a plurality of dielectric sub-layer 11, wherein the dielectric sub-layer 11 and the metal grain layers 12 are disposed alternatively. The amount of the metal grain layers and the dielectric sub-layers are not limited in the embodiment, and will be determined according to actual requirements. It should be noted that, in a system with a plurality of metal grain layers 12 and a plurality of dielectric sub-layers 11, it is a dielectric sub-layer 11 that is disposed outmost. The dielectric sub-layers 11 are made of at least one of silicon oxide or silicon nitride, and each of the dielectric sub-layers 11 has a thickness of 2 nm to 10 nm.

The metal grain layer 12 is made of at least one of Au (aurum), Ag (argent), or Al (aluminum). Of course, the metal grain layer 12 can also be made of a composite structure of other metals. Metal grain in the metal grain layer 12 has a shape of sphere, cylinder, cuboid, cube, cage, or core-shell, and has a size of 1 nm to 4 nm, and all the metal grains have different sizes so that energies of surface plasmons of metal grains that resonates correspond to different wavelengths, thereby effectively enhancing light emitting efficiency of the OLED 3. In the embodiments of the present disclosure, one to five metal grain layers 12 are disposed. Of course, the amount of the metal grain layers 12 is not limited herein and can be determined according to actual requirements.

At least one embodiment of the present disclosure provides an OLED display panel, which comprises the display substrate described above, i.e., the array substrate described above, and further comprises, of course, a package cover plate disposed at a side of the OLED device away from the light emitting surface.

The OLED display panel can be any product or component having display function, such as a cell phone, a tablet computer, a television, a display, a laptop, a digital photo frame, a navigator and etc.

The OLED display panel according to the disclosure comprises the array substrate described above, thereby having a better light outgoing efficiency and a better visual effect.

Of course, the OLED display panel according to the embodiment further comprises other common components, such as a power unit, a display driving unit, and the like.

As illustrated in FIG. 2, at least one embodiment of the present disclosure provides a display panel, which is a package cover plate for an OLED display panel. The OLED display panel utilizes an OLED device 3 which is a top emission OLED device. A dielectric layer is provided between a base substrate 1 of the package cover plate and the OLED device 3, and at least one metal grain layer 12 is provided in the dielectric layer.

If the OLED device 3 utilized in the OLED display panel is a top emission OLED device, when light emitted from the OLED device 3 is incident on the metal grain layer 12 on the base substrate 1 of the package cover plate, light outgoing efficiency of the OLED device is enhanced through the surface plasmons resonance effect of metal grains in the metal grain layer 12, thereby enhancing light outgoing efficiency of the display panel. Operation principle of the display panel is the same as the array substrate described above, and will not be elaborated herein.

The package cover plate can comprises a plurality of metal grain layers 12, and the dielectric layer comprises a plurality of dielectric sub-layer 11, wherein the dielectric sub-layers 11 and the grain metal grain layers are alternately disposed in a direction perpendicular to the base substrate 1. In the disclosure, the amounts of the metal grain layers 12 and of the dielectric sub-layers 11 are not limited, and can be determined according to actual requirements. It should be noted that, each of the metal grain layers 12 is sandwiched between two dielectric sub-layers 11. For example, the dielectric sub-layers 11 are made of silicon oxide or silicon nitride, and each of the dielectric sub-layers 11 has a thickness of 2 nm to 10 nm.

The metal grain layers 12 are made of at least one of Au, Ag, or Al. Of course, the metal grain layer 12 can also be made of a composite structure of other metals. Metal grain in the metal grain layer 12 has a shape of sphere, cylinder, cuboid, cube, cage, or core-shell, and has a size of 1 nm to 4 nm, and all the metal grains have different sizes so that energies of surface plasmons of metal grains that resonate correspond to different wavelengths, thereby effectively enhancing light emitting efficiency of the OLED 3. In the embodiments of the present disclosure, one to five metal grain layers 12 are disposed. Of course, the amount of the metal grain layers 12 is not limited herein and can be determined according to actual requirements.

As described above, in the embodiment of the present disclosure, a light emitting surface of the OLED device faces the package cover plate, and a dielectric layer is disposed between the OLED device and the package cover plate. As the metal grain layer 12 is disposed in the dielectric layer, thus light emitting efficiency of the OLED 3 is significantly enhanced when the light emitted from the OLED device 3 disposed over the array substrate, thereby enhancing light outgoing efficiency of the display panel.

In embodiments of the present disclosure, the OLED display panel can be any product or component having display function, such as a cell phone, a tablet computer, a television, a display, a laptop, a digital photo frame, a navigator and etc.

The OLED display panel according to the disclosure comprises the array substrate described above, thereby having a better light outgoing efficiency and a better visual effect.

Of course, the OLED display panel according to the embodiment further comprises other common components, such as a power unit, a display driving unit, and the like.

At least one embodiment of the present disclosure provides a method for manufacturing a display substrate, which comprises forming a dielectric layer over a base substrate 1 and forming at least one metal grain layer 12 in the dielectric layer.

For example, as illustrated in FIG. 4, firstly, a dielectric sub-layer 11 is formed on a base substrate 1 through sputtering, thermal evaporation, plasma enhanced vapor deposition (PECVD), low pressure chemical vapor deposition (LPCVD), atmospheric pressure chemical vapor deposition (APCVD), or electron cyclotron resonance chemical vapor deposition (ECR-CVD), and then a layer 20 of metal material is formed on the dielectric sub-layer 11 through sputtering or physical vapor deposition. Then, the processes described above are repeated and a plurality of dielectric sub-layers 11 and a plurality of layers of metal material. In one embodiment of the present disclosure, there are two to five sub electric layers 11 and layers 20 of metal material are formed. In one embodiment of the present disclosure, a dielectric sub-layer 11 is formed at the end, as the outmost layer of lamination of dielectric sub-layers and layers of metal material. In one embodiment of the present disclosure, the dielectric sub-layers 11 are made of at least one of silicon oxide or silicon nitride, and each of the dielectric sub-layers 11 has a thickness of 2 nm to 10 nm. The layers 20 of metal material can be made of at least one of Au, Ag, or Al. Of course, the layers 20 of metal material can also be made of composite structures of other metals. Each of the layers 20 of metal material has a thickness of 1 nm to 5 nm.

Then, the base substrate 1 is subject to annealing for 5 minutes to 30 minutes at a temperature of 300° C. to 500° C., such that metal atoms in the layers 20 of metal material are fused and diffused, and clustered to metal grains. The longer durance of the annealing is, the greater the formed metal grains are.

On the base substrate 1 subjected to annealing, a driving transistor 2 and an OLED device 3 are formed, wherein the OLED device 3 is a bottom emission OLED device. A method for manufacturing the driving transistor 2 and the OLED device 3 is a conventional one, and will not be elaborated herein. Up to now, the array substrate is completed.

The method further comprises packaging the array substrate and the package cover plate.

At least one embodiment of the present disclosure provides a method for manufacturing a display panel, which is a package cover plate. As illustrated in FIG. 4, the method for manufacturing the package cover plate according to the embodiment comprises:

Firstly, a dielectric sub-layer 11 is formed on a base substrate 1 through sputtering, thermal evaporation, plasma enhanced vapor deposition (PECVD), low pressure chemical vapor deposition (LPCVD), atmospheric pressure chemical vapor deposition (APCVD), or electron cyclotron resonance chemical vapor deposition (ECR-CVD), and then a layer 20 of metal material is formed on the dielectric sub-layer 11 through sputtering or physical vapor deposition. Then, the processes described above are repeated, for example, for 2 to 5 times, and a plurality of dielectric sub-layers 11 and a plurality of layers of metal material are formed, and a dielectric sub-layer 11 is formed finally. The dielectric sub-layers 11 are made of at least one of silicon oxide or silicon nitride, and each of the dielectric sub-layers 11 has a thickness of 2 nm to 10 nm. The layers 20 of metal material can be made of at least one of Au, Ag, or Al. Of course, the layers 20 of metal material can also be made of composite structures of other metals. Each of the layers 20 of metal material has a thickness of 1 nm to 5 nm.

Then, the base substrate 1 is subject to annealing for 5 minutes to 30 minutes at a temperature of 300° C. to 500° C., such that metal atoms in the layers 20 of metal material are fused and diffused, and clustered to metal grains. The longer durance of the annealing is, the greater the formed metal grains are.

Up to now, the package cover plate is completed.

The method further comprises providing an array substrate and packaging the array substrate and the package cover plate, wherein the array substrate comprises a driving transistor 2 and an OLED which is a top emission type OLED, and finally, cell-assembling the array substrate and the package cover plate. Then, the OLED display panel is completed.

As described above, an OLED display panel manufactured by the method for manufacturing an OLED according to the embodiment of the present disclosure has good light-emitting efficiency and provides good visual effect.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201610028669.0 filed on Jan. 15, 2016, the disclosure of which is hereby entirely incorporated by reference.

1. A dielectric layer applicable to a display substrate, comprising at least one metal grain layer which is disposed in the dielectric layer.

2. The dielectric layer according to claim 1, further comprising a plurality of metal grain layers and a plurality of dielectric sub-layers, wherein the plurality of metal grain layers and the plurality of dielectric sub-layers are disposed alternately, and each of the metal grain layers is sandwiched between adjacent two dielectric sub-layers.

3. The dielectric layer according to claim 1, wherein the plurality of dielectric sub-layers are made of at least one of silicon oxide or silicon nitride.

4. The dielectric layer according to claim 1, wherein each of the plurality of dielectric sub-layers has a thickness of 2 nm to 10 nm.

5. The dielectric layer according to claim 1, wherein the metal grain layer is made of at least one of Au, Ag or Al, or combination thereof.

6. The dielectric layer according to claim 1, wherein metal grains in the metal grain layer has a size of 1 nm to 4 nm.

7. The dielectric layer according to claim 1, wherein metal grains in the metal grain layer has a shape of sphere, cylinder, cuboid, cube, cage, or core-shell.

8. A display substrate, comprising the dielectric layer according to claim 1, and further comprising a substrate and an OLED device, a light emitting surface of the OLED device facing the substrate, wherein the dielectric layer is disposed between the substrate and the OLED device.

9. The display substrate according to claim 8, further comprising a driving transistor, wherein the driving transistor is disposed over the dielectric layer, and a drain electrode of the driving transistor is electrically connected to the OLED device.

10. The display substrate according to claim 8, further comprising a package cover plate, which is disposed at a side of the OLED device away from the light emitting surface.

11. A display substrate, comprising the dielectric layer according to claim 1, and further comprising a substrate, an OLED device and a package cover plate, wherein the OLED device is disposed between the substrate and the package cover plate, a light emitting surface of the OLED device faces the package cover plate, and the dielectric layer is disposed between the OLED device and the package cover plate.

12. The display substrate according to claim 11, wherein the display substrate further comprises a driving transistor is disposed over the dielectric layer, and a drain electrode of the driving transistor is electrically connected to the OLED device.

13. A method for manufacturing the display substrate according to claim 8, which comprising:
forming a dielectric layer and forming at least one metal grain layer in the dielectric layer.

14. The method according to claim 13, wherein the display substrate comprises a plurality of metal grain layers and the dielectric layer comprises a plurality of dielectric sub-layers, and the plurality of metal grain layers and the plurality of dielectric sub-layers are disposed alternately in a direction perpendicular to the base;
forming a dielectric layer and forming at least one metal grain layer in the dielectric layer comprising:
forming a plurality of metal material layers and a plurality of dielectric sub-layers on the base which are disposed alternately;
forming a dielectric sub-layer on the base on which the plurality of metal material layers and the plurality of dielectric sub-layers are formed; and
annealing the display substrate, so as to make metal atoms in the metal material layer cluster into metal grains and form the metal grain layers.

15. The method according to claim 13, wherein the annealing is performed at a temperature of 300° C. to 500° C. for 5 minutes to 30 minutes.

16. A method for manufacturing an OLED display panel, comprising the method according to claim 12.
